(19) United States
(12) Patent Application Publication
(10) Pub. No.: US 2024/0116086 A1
(43) Pub. Date: Apr. 11, 2024

(54) SUBSTRATE PROCESSING FACILITY AND SUBSTRATE PROCESSING METHOD

(71) Applicant: SEMES CO., LTD., Chungcheongranm-do (KR)

(72) Inventors: Yong Hyun CHOI, Chungcheongnam-do (KR); Woo Young KIM, Chungcheongnam-do (KR); Dong Gyu JIN, Chungcheongnam-do (KR)

(21) Appl. No.: 18/117,524

(22) Filed: Mar. 6, 2023

(30) Foreign Application Priority Data
May 19, 2022 (KR) 10-2022-0061322

(51) Int. Cl. B08B 3/08; B08B 3/02; B08B 5/00; B08B 7/00; B08B 7/04

(52) U.S. Cl. CPC B08B 3/08; B08B 3/02; B08B 5/00; B08B 7/0071; B08B 7/04; B08B 2220/01; F26B 3/06

(57) ABSTRACT

A substrate processing facility includes a cleaning device for cleaning a substrate; and a drying device for drying the substrate cleaned by the cleaning device with a supercritical gas, wherein the cleaning device includes a sulfuric acid cleaning chamber.

### CROSS-REFERENCE TO RELATED APPLICATIONS

The application claims benefit of priority to Korean Patent Application No. 10-2022-0061322 filed on May 19, 2022 in the Korean Intellectual Property Office, the disclosure of which is incorporated herein by reference in its entirety.

### BACKGROUND

### 1. Field

Embodiments of the present disclosure relate to a substrate processing facility and a substrate processing method.

### 2. Description of Related Art

Ina substrate process of a semiconductor manufacturing process, a substrate may go through a supercritical gas drying treatment after general cleaning. That is, a substrate may be wet-transferred to a supercritical gas dryer after a general cleaning treatment, before being dried with supercritical gas, and a drying treatment may be performed.

Meanwhile, in a separate substrate process, sulfuric acid cleaning may be performed, in which a cleaning solution containing a mixture of sulfuric acid and hydrogen peroxide may be used to peel off a resist applied to the substrate or to remove organic substances attached to the surface of the substrate.

A general substrate processing facility may have an installation structure in which a supercritical gas drying device is configured together with a general cleaning device, and may not have a structure associated with a sulfuric acid cleaning device.

### SUMMARY

An embodiment of the present disclosure is to provide a substrate processing facility and a substrate processing method which may dry a substrate with supercritical gas after cleaning the substrate with sulfuric acid.

According to an embodiment of the present disclosure, a substrate processing facility includes a cleaning device for cleaning a substrate; and a drying device for drying the substrate cleaned by the cleaning device with a supercritical gas, wherein the cleaning device includes a sulfuric acid cleaning chamber.

The cleaning device may include at least one first treatment tank and at least one second treatment tank, and at least one of the first treatment tank and the second treatment tank may include the sulfuric acid cleaning chamber, and the drying device may include at least one third treatment tank, and the third treatment tank may be a supercritical gas drying chamber.

One of the first treatment tank and the second treatment tank may be a general cleaning chamber using one of SC1, HF, LAL, and IPA, which are cleaning solutions, and the other thereof may be the sulfuric acid cleaning chamber.

The first treatment tank and the second treatment tank may be used as a general cleaning chamber using one of SC1, HF, LAL, and IPA, which are cleaning solutions, and the sulfuric acid cleaning chamber.

According to an embodiment of the present disclosure, a substrate processing method includes a cleaning step of cleaning a substrate; and a supercritical drying step of drying the cleaned substrate with supercritical gas, wherein the cleaning step includes a sulfuric acid cleaning step.

The cleaning step may include a general cleaning step of cleaning the substrate with one of SC1, HF, LAL and IPA, which are cleaning solutions; and the sulfuric acid cleaning step of cleaning the substrate with sulfuric acid, the general cleaning step, the sulfuric acid cleaning step, and the supercritical drying step may be performed in sequence.

The cleaning step may include a general cleaning step of cleaning a portion of a plurality of the substrates with one of SC1, HF, LAL, and IPA, cleaning solutions; and the sulfuric acid cleaning step of cleaning the rest of the plurality of substrates with sulfuric acid, the general cleaning step and the supercritical drying step may be performed in sequence, and the sulfuric acid cleaning step and the supercritical drying step may be performed in sequence.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating a general substrate processing facility;

FIG. 2 is a diagram illustrating a substrate processing facility according to a first embodiment of the present disclosure;

FIG. 3 is a diagram illustrating a substrate processing facility according to a second embodiment of the present disclosure;

FIG. 4 is a diagram illustrating a substrate processing facility according to a third embodiment of the present disclosure;

FIG. 5 is a diagram illustrating a substrate processing method according to a first embodiment of the present disclosure;

FIG. 6 is a diagram illustrating a substrate processing method according to a second embodiment of the present disclosure; and

FIG. 7 is a diagram illustrating a substrate processing method according to a third embodiment of the present disclosure.

### DETAILED DESCRIPTION

Hereinafter, embodiments of the present disclosure will be described as below with reference to the attached drawings.

In the drawings, same elements will be indicated by same reference numerals. Also, redundant descriptions and detailed descriptions of known functions and elements that may unnecessarily make the gist of the present disclosure obscure will be omitted. In the accompanying drawings, some elements may be exaggerated, omitted or briefly illustrated, and the sizes of the elements do not necessarily reflect the actual sizes of these elements. Also, the terms “upper,” “upper portion,” “upper surface,” “lower,” “lower portion,” “lower surface,” “side surface” are based on the drawings, and may be varied in a direction in which the components are disposed.

In the embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” The terms, “include,” “comprise,” “is configured to,” or the like of the description may be used to indicate the presence of features, numbers, steps, operations, elements, portions or combination thereof, and do not exclude the possibilities of combination or addition of one or more features, numbers, steps, operations, elements, portions or combination thereof.

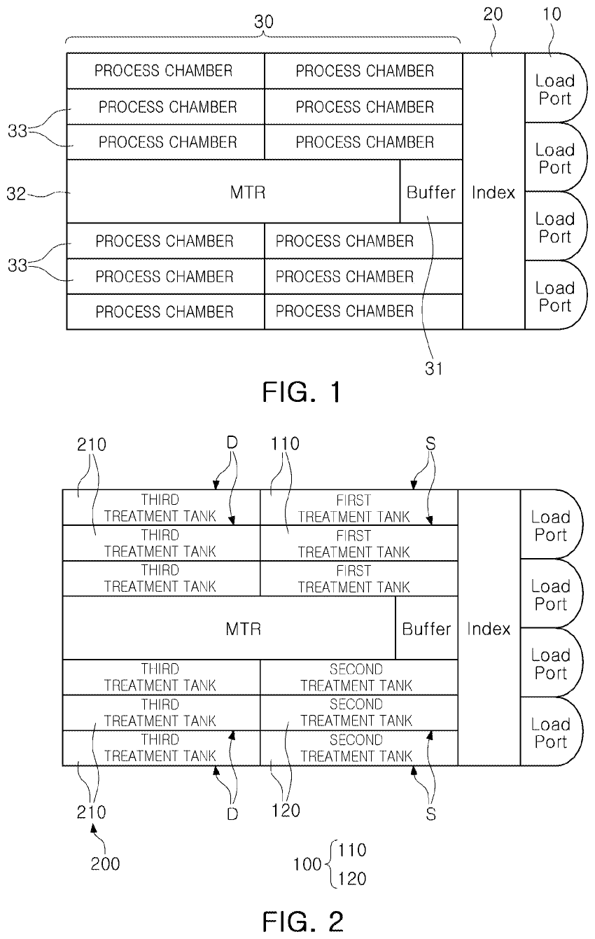

FIG. 1 is a diagram illustrating a general substrate processing facility.

Referring to the drawing, an index module 20 may receive a substrate from the outside, and may transfer the substrate to the process module 30. The index module 20 may be an equipment front end module (EFEM).

A load port 10 may be disposed on the front end of the index module 20. A container in which a substrate is accommodated may be disposed in the load port 10. A front opening unified pod (FOUP) may be used as the container. The container may be carried in from the outside to the load port 10 or may be carried out from the load port 10 by an overhead hoist transfer (OHT).

The index module 20 may transfer the substrate between the container disposed on the load port 10 and the process module 30. To this end, the index module 20 may include an index robot moving on an index rail.

The process module 30 may include a buffer chamber 31, a transfer chamber 32, and a plurality of process chambers 33. The buffer chamber 31 may provide a space in which a substrate transported between the index module 20 and the process module 30 temporarily stays. A plurality of buffer slots may be disposed in the buffer chamber 31. The index robot of the index module 20 may remove the substrate from the container of the load port and may dispose the substrate in the buffer slot of the buffer chamber.

The transfer robot (MTR, Main Transfer Robot) of the transfer chamber 32 may remove the substrate disposed in the buffer slot, and may transfer the substrate to a predetermined process chamber among the plurality of process chambers 33 (e.g., the first treatment tank). Also, the transfer robot of the transfer chamber 32 may transfer the substrate from one of the plurality of process chambers 33 (e.g., the first treatment tank) to another process chamber (e.g., the third treatment tank).

The plurality of process chambers 33 may be arranged linearly, may be stacked vertically, or may be disposed in both manners described above. As illustrated in the drawing, a plurality of partial process chambers (the first treatment tank, and the third treatment tank on one side) and a plurality of other process chambers (the second treatment tank, and third treatment tank on the other side) may be disposed on both sides of the transfer chamber 32. The arrangement of the plurality of process chambers 33 is not limited to the above example, and may be changed in consideration of the footprint or process efficiency of a substrate processing facility.

As illustrated in FIGS. 2 to 4, the embodiment may include a cleaning device 100 and a drying device 200. The cleaning device 100 may clean the substrate. The cleaning device 100 may include at least one first treatment tank 110 and at least one second treatment tank 120. In this case, at least one of the first treatment tank 110 and the second treatment tank 120 may include a sulfuric acid cleaning chamber S.

The drying device 200 may include at least one third treatment tank 210, and the third treatment tank 210 may be a supercritical gas drying chamber D.

FIG. 2 is a diagram illustrating a substrate processing facility according to a first embodiment.

Referring to the drawing, in the cleaning device 100, the first treatment tank 110 and the second treatment tank 120 may be used as a sulfuric acid cleaning chamber S. Accordingly, the substrate may be cleaned with high-temperature sulfuric acid in the first treatment bath 110 and the second treatment bath 120. Among the cleaning solutions, ammonia, hydrogen peroxide, and sulfuric acid may become more acidic. Ammonia cleaning may include cleaning organic residues, hydrogen peroxide cleaning may include removing even metallic residues, and sulfuric acid cleaning may include removing organic and metallic contaminants as well as the remaining photoresist (PR) film used for development during the photo process. The sulfuric acid cleaning may be also called piranha (piranha) cleaning because the reaction may occur in the same manner as piranhas rush.

In the drying device 200, the third treatment tank 210 may be used as a supercritical gas drying chamber D. The supercritical gas drying chamber D may dry the substrate cleaned by the cleaning device 100 with supercritical gas. The supercritical gas may be used as a drying gas in the process chamber and may dry the substrate in the process chamber. Carbon dioxide (CO₂) may be used as the supercritical fluid, for example. The substrate may be supercritically dried by carbon dioxide at a critical temperature (31° C.) and a critical pressure (73.8 bar) or higher. Due to micronization, the super critical gas may combine with the chemical or pure water and may remove contaminants in a place in which chemicals or pure water (DIW) cannot permeate.

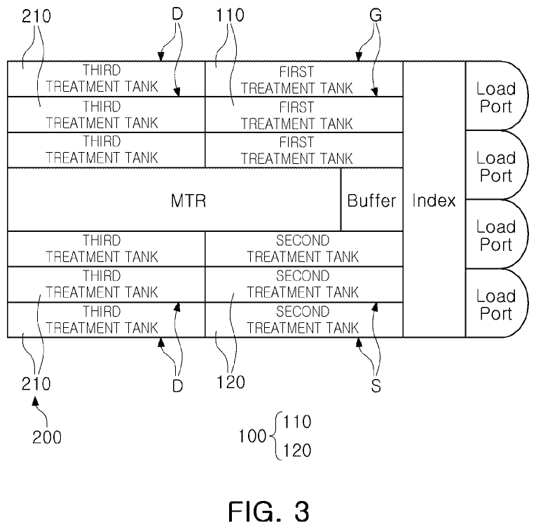

FIG. 3 is a diagram illustrating a substrate processing facility according to a second embodiment.

Referring to the drawing, in the cleaning device 100, one of the first treatment tank 110 and the second treatment tank 120 may be a general cleaning chamber G, and the other thereof may be a sulfuric acid cleaning chamber S.

The general cleaning chamber G may clean the substrate using one of the SC1, HF, LAL and IPA, which may be cleaning solutions. standard cleaning 1 (SC1) may be an ammonium peroxide mixture (APM), which may be a mixture of ammonia water (NH₄OH), hydrogen peroxide (H₂O₂), and water (H₂O). LAL may be referred to as a buffered oxide etchant (BOE), and may be a mixture of amonium fluoriede, ammonium fluoride (NH₄F) and hydrofluoric acid (HF). Also, hydrofluoric acid (HF) and isopropyl alcohol (IPA) may also be used as substrate cleaning liquids.

After the substrate is cleaned with one of SC1, HF, LAL, and IPA in the general cleaning chamber G, to remove photoresist or other residues not completely removed, the substrate may be cleaned with high-temperature sulfuric acid in the sulfuric acid cleaning chamber S.

The substrate may be cleaned in the second treatment tank 120 after being cleaned in the first treatment tank 110, or may be cleaned in the first treatment tank 110 after being cleaned in the second treatment tank 120. In this case, a treatment tank to be cleaned first may be a general cleaning chamber G, and a treatment tank to be cleaned later may be a sulfuric acid cleaning chamber S. As an example, in FIG. 3, the first treatment tank 110 may be a general cleaning chamber G, and the second treatment tank 120 may be a sulfuric acid cleaning chamber S.

In the drying device 200, the third treatment tank 210 may be a supercritical gas drying chamber D. The supercritical gas drying chamber D may dry the substrate cleaned by the cleaning device 100 with supercritical gas. That is, the substrate may be cleaned in the general cleaning chamber G, may be washed in sulfuric acid in the sulfuric acid cleaning chamber S, and may be wet-transferred to the supercritical gas drying chamber D and may be dried with supercritical gas.

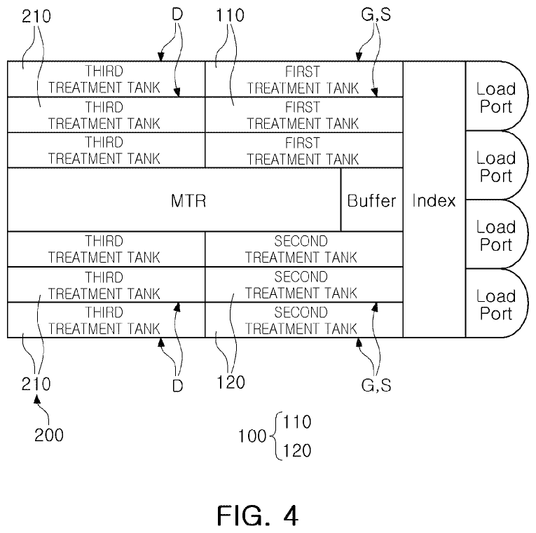

FIG. 4 is a diagram illustrating a substrate processing facility according to a third embodiment.

Referring to the drawings, the first treatment tank 110 and the second treatment tank 120 may be used as a general cleaning chamber G and a sulfuric acid cleaning chamber S. That is, both the first treatment tank 110 and the second treatment tank 120 may first be used as a general cleaning chamber G and may be used as a sulfuric acid cleaning chamber S.

Specifically, both the first treatment tank 110 and the second treatment tank 120 may be first used as a general cleaning chamber G, and the substrate may be cleaned with one of SC1, HF, LAL, and IPA, which are cleaning solutions. Thereafter, both the first treatment tank 110 and the second treatment tank 120 may be used as a sulfuric acid cleaning chamber S, and the substrate may be cleaned with high-temperature sulfuric acid as a cleaning solution. In this case, the first treatment tank 110 and the second treatment tank 120 may be used as a general cleaning chamber G when one of SC1, HF, LAL, and IPA cleaning solution is discharged to the substrate through a nozzle. Also, the first treatment tank 110 and the second treatment tank 120 may be used as a sulfuric acid cleaning chamber S when high-temperature sulfuric acid is discharged to the substrate through a nozzle.

In the drying device 200, the third treatment tank 210 may be a supercritical gas drying chamber D. The supercritical gas drying chamber D may dry the substrate cleaned by the cleaning device 100 with supercritical gas. That is, after the substrate is general-cleaned using both the first treatment tank 110 and the second treatment tank 120 as the general cleaning chamber G, the substrate may be sulfuric acid-cleaned using both the first treatment tank 110 and the second treatment tank 120 as sulfuric acid cleaning chambers S, and the substrate may be wet-transferred to the supercritical gas drying chamber D and may be dried by supercritical gas.

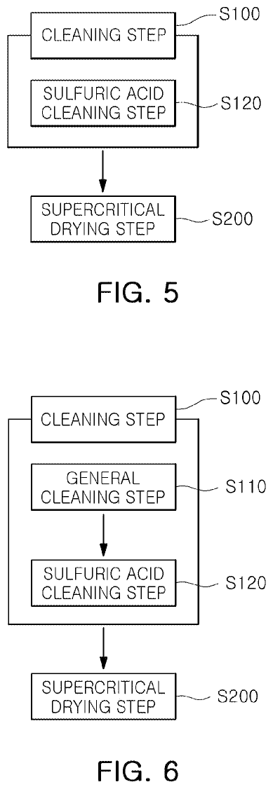

As illustrated in FIGS. 5 to 7, the embodiment may include a cleaning step (S100) and a supercritical drying step (S200). The cleaning step (S100) may be of cleaning the substrate. In this case, the cleaning step (S100) may include a sulfuric acid cleaning step (S120). The supercritical drying step (S200) may be of drying the substrate cleaned in the cleaning step (S100) with a supercritical gas.

FIG. 5 is a diagram illustrating a substrate processing method according to a first embodiment.

Referring to the drawing, a sulfuric acid cleaning step (S120) may be performed in the cleaning step (S100), and in this case, the substrate may be cleaned with high-temperature sulfuric acid. By the sulfuric acid cleaning, organic and metallic contaminants and also a photoresist (PR) film remaining after being used for development during the photo process may be removed.

After the supercritical drying step (S200), the substrate may be dried with supercritical gas. Due to micronization, the super critical gas may combine with the chemical or pure water and may remove contaminants in a place in which the chemical or pure water cannot permeate.

FIG. 6 is a diagram illustrating a substrate processing method according to a second embodiment.

Referring to the drawing, the cleaning step (S100) may include a general cleaning step (S110) and a sulfuric acid cleaning step (S120).

The general cleaning step (S110) may be of cleaning the substrate with one of the cleaning solutions SC1, HF, LAL and IPA. The sulfuric acid cleaning step (S120) may be of cleaning the substrate with sulfuric acid.

After the substrate is cleaned with one of SC1, HF, LAL, and IPA in the general cleaning step (S110), to remove photoresist or other residues not completely removed, the substrate may be cleaned with high-temperature sulfuric acid in the sulfuric acid cleaning step (S120).

In the supercritical drying step (S200), the substrate cleaned through the cleaning step (S100) may be dried with supercritical gas. The general cleaning step (S110), the sulfuric acid cleaning step (S120), and the supercritical drying step (S200) may be performed in sequence. That is, the substrate may be cleaned in the general cleaning step (S110), may be washed in sulfuric acid in the sulfuric acid cleaning step (S120), may be wet-transferred to the supercritical gas drying chamber D and may be dried with supercritical gas.

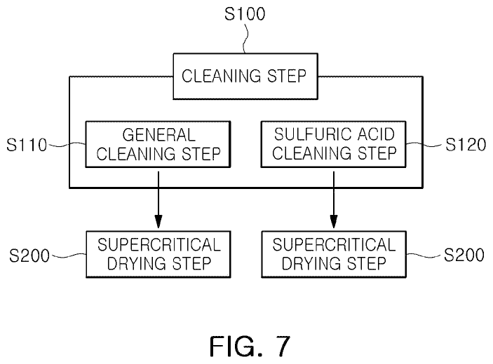

FIG. 7 is a diagram illustrating a substrate processing method according to a third embodiment.

Referring to the drawing, the cleaning step (S100) may include a general cleaning step (S110) and a sulfuric acid cleaning step (S120).

The general cleaning step (S110) may be of cleaning a portion of the plurality of substrates with one of cleaning solutions SC1, HF, LAL, and IPA. The sulfuric acid cleaning step (S120) may be of cleaning the rest of the plurality of substrates with sulfuric acid.

That is, a portion of the plurality of substrates may go through the general cleaning step (S110), and the rest may go through the sulfuric acid cleaning step (S120).

In the supercritical drying step (S200), the substrate cleaned through the cleaning step (S100) may be dried with supercritical gas. Specifically, the general cleaning step (S110) and the supercritical drying step (S200) may be performed in sequence, and the sulfuric acid cleaning step (S120) and the supercritical drying step (S200) may be performed in sequence.

According to an embodiment, the substrate processing facility and the substrate processing method may have the effect of improving the removal rate of contaminants on the substrate by cleaning the substrate with sulfuric acid and drying the substrate with a supercritical gas.

While the embodiments have been illustrated and described above, it will be apparent to those skilled in the art that modifications and variations could be made without departing from the scope of the present disclosure as defined by the appended claims.

What is claimed is:

1. A substrate processing facility, comprising:
a cleaning device for cleaning a substrate; and
a drying device for drying the substrate cleaned by the cleaning device with a supercritical gas,
wherein the cleaning device includes a sulfuric acid cleaning chamber.

2. The substrate processing facility of claim 1,
wherein the cleaning device includes at least one first treatment tank and at least one second treatment tank, and at least one of the first treatment tank and the second treatment tank includes the sulfuric acid cleaning chamber, and
wherein the drying device includes at least one third treatment tank, and the third treatment tank is a supercritical gas drying chamber.

3. The substrate processing facility of claim 2,
wherein one of the first treatment tank and the second treatment tank is a general cleaning chamber using one of SC1, HF, LAL, and IPA, which are cleaning solutions, and the other thereof is the sulfuric acid cleaning chamber.

4. The substrate processing facility of claim 2,
wherein the first treatment tank and the second treatment tank are used as a general cleaning chamber using one of SC1, HF, LAL, and IPA, which are cleaning solutions, and the sulfuric acid cleaning chamber.

5. A substrate processing method, comprising:
a cleaning step of cleaning a substrate; and
a supercritical drying step of drying the cleaned substrate with supercritical gas,
wherein the cleaning step includes a sulfuric acid cleaning step.

6. The substrate processing method of claim 5,
wherein the cleaning step includes:
a general cleaning step of cleaning the substrate with one of SC1, HF, LAL and IPA, which are cleaning solutions; and
the sulfuric acid cleaning step of cleaning the substrate with sulfuric acid,
wherein the general cleaning step, the sulfuric acid cleaning step, and the supercritical drying step are performed in sequence.

7. The substrate processing method of claim 5,
wherein the cleaning step includes:
a general cleaning step of cleaning a portion of a plurality of the substrates with one of SC1, HF, LAL, and IPA, cleaning solutions; and
the sulfuric acid cleaning step of cleaning the rest of the plurality of substrates with sulfuric acid,
wherein the general cleaning step and the supercritical drying step are performed in sequence, and the sulfuric acid cleaning step and the supercritical drying step are performed in sequence.
